(19) United States
(12) Patent Application Publication
(10) Pub. No.: US 2026/0260855 A1
(43) Pub. Date: Sep. 3, 2026

(54) LOW-TEMPERATURE ELECTROSTATIC CHUCK

(71) Applicant: EST, INC., Gyeonggi-do (KR)

(72) Inventors: Young Gon KIM, Gyeonggi-do (KR); Jae Hyuk PARK, Gyeonggi-do (KR); Byung Jun HAN, Gyeonggi-do (KR); Nam Hui LEE, Gyeonggi-do (KR); Jong Woo LIM, Gyeonggi-do (KR)

(21) Appl. No.: 18/841,778

(22) PCT Filed: Feb. 23, 2023
(86) PCT No.: PCT/KR2023/002411

§ 371 Date: Aug. 27, 2024

(30) Foreign Application Priority Data
Feb. 28, 2022 (KR) 10-2022-0025978
Feb. 28, 2022 (KR) 10-2022-0025979
Dec. 6, 2022 (KR) 10-2022-0169190
Dec. 6, 2022 (KR) 10-2022-0169191

(51) Int. Cl. H01J 37/32; H10P 72/72

(52) U.S. Cl. CPC H01J 37/32724; H10P 72/722

(57) ABSTRACT

The present invention relates to a low-temperature electrostatic chuck, and is intended to solve the technical problem of providing a low-temperature electrostatic chuck that can be mounted on equipment without frost, ice, or moisture being formed on the equipment. To this end, the present invention provides a low-temperature electrostatic chuck comprising: a base member; and a support member composed of a first dielectric layer coated on the base member, an electrode layer provided on the first dielectric layer, and a second dielectric layer coated on the first dielectric layer and the electrode layer, wherein the base member includes a first flow path in an upper region through which a first fluid having a first temperature flows, and a second flow path in a lower region through which a second fluid having a second temperature higher than the first temperature flows.

### TECHNICAL FIELD

The present disclosure relates to a low-temperature electrostatic chuck.

### BACKGROUND ART

Generally, semiconductor devices are manufactured through a plurality of unit processes including a thin film deposition process and an etching process, and the etching process is mainly performed using a plasma etching apparatus in which a plasma reaction is induced.

Recently, it has become necessary to perform plasma etching at a low temperature to secure high selectivity when forming a structure having a high aspect ratio or etching a wafer using a photoresist film.

For such low-temperature etching, electrostatic chucks are also in a low-temperature state, which cause various problems in equipment to which the electrostatic chuck is coupled and mounted. For example, since the electrostatic chuck is in a low-temperature state and the equipment is at room temperature, frost, ice, or water may be formed on the equipment. Such moisture can affect various mechanical/electrical structures of the equipment and eventually cause wafer defects.

The above-described information disclosed in the background art of the present invention is only for improving understanding of the background of the present invention, and therefore may include information that does not constitute the related art.

### DETAILED DESCRIPTION OF THE DISCLOSURE

### Technical Problems to be Solved

The present disclosure is directed to providing a low-temperature electrostatic chuck which does not form frost, ice, moisture, or the like on equipment and is capable of being mounted on the equipment.

### Technical Solutions

According to an aspect of the present disclosure, there is provided a low-temperature electrostatic chuck which includes a base member, and a support member including a first dielectric layer applied on the base member, an electrode layer provided on the first dielectric layer, and a second dielectric layer applied on the first dielectric layer and the electrode layer, wherein the base member includes first flow paths provided in an upper region and through which a first fluid at a first temperature flows, and second flow paths provided in a lower region and through which a second fluid at a second temperature higher than the first temperature flows.

The first temperature may range from —200°C to 0° C., and the second temperature may range from 0° C. to 80° C.

The base member may further include a heat-blocking cavity provided between the first flow path and the second flow path.

The heat-blocking cavity may include a first heat-blocking cavity provided between the first flow paths and the second flow paths, and a second heat-blocking cavity which is provided between the first flow paths and connected to the first heat-blocking cavity.

The heat-blocking cavity may include a first heat-blocking cavity provided between the first flow paths and the second flow paths, and a second heat-blocking cavity which is provided between the second flow paths and connected to the first heat-blocking cavity.

The heat-blocking cavity may include a first heat-blocking cavity provided between the first flow paths and the second flow paths, a second heat-blocking cavity provided between the first flow paths and connected to the first heat-blocking cavity, and a third heat-blocking cavity provided between the second flow paths and connected to the first heat-blocking cavity.

An inside of the heat-blocking cavity may be filled with a heat insulating material.

An upper or lower surface of the heat-blocking cavity may be coated with yttria-stabilized zirconia (YSZ) or coupled to an YSZ plate or may be coated with Al₂TiO₅ or coupled to an Al₂TiO₅ plate.

The base member may further include a heat-blocking heater provided between the first flow path and the second flow path.

The base member may further include a heat-blocking cavity provided between the first flow path and the second flow path, and a heat-blocking heater provided between the first flow path and the second flow path.

The low-temperature electrostatic chuck may further include a bonding layer interposed between the base member and the support member.

The bonding layer may include a silicone polymer-based material or a metal-based material.

The bonding layer may include at least one of one-component silicone, two-component silicone, one-component epoxy, two-component epoxy, and polyurethane having a thermal conductivity of 0.3 W/mK to 3 W/mK.

The bonding layer may include at least one of a ceramic filler and a metal filler.

The bonding layer may include a metalized brazing layer, an active metal brazing layer, a diffusion bonding layer, a friction welding layer, or a laser welding layer between the base member and the support member.

### Advantageous Effects of Disclosure

According to the present disclosure, a low-temperature electrostatic chuck which does not form frost, ice, moisture, or the like on equipment and can be mounted on the equipment can be provided.

### BRIEF DESCRIPTION OF THE DRAWINGS

FIG. 1 is a cross-sectional view illustrating an exemplary low-temperature electrostatic chuck according to the present disclosure.

FIGS. 2A to 2D are cross-sectional views illustrating a method of manufacturing an exemplary low-temperature electrostatic chuck according to the present disclosure.

FIGS. 3A and 3B are cross-sectional views illustrating exemplary low-temperature electrostatic chucks according to the present disclosure.

FIG. 4 is a cross-sectional view illustrating an exemplary low-temperature electrostatic chuck according to the present disclosure.

FIGS. 5A to 5C are cross-sectional views illustrating exemplary low-temperature electrostatic chucks according to the present disclosure.

FIG. 6 is a cross-sectional view illustrating an exemplary low-temperature electrostatic chuck according to the present disclosure.

FIG. 7 is a cross-sectional view illustrating an exemplary low-temperature electrostatic chuck according to the present disclosure.

FIGS. 8A to 8C are cross-sectional views illustrating a method of manufacturing an exemplary low-temperature electrostatic chuck according to the present disclosure.

FIGS. 9A and 9B are cross-sectional views illustrating exemplary low-temperature electrostatic chucks according to the present disclosure

FIG. 10 is a cross-sectional view illustrating an exemplary low-temperature electrostatic chuck according to the present disclosure.

FIGS. 11A to 11C are cross-sectional views illustrating exemplary low-temperature electrostatic chucks according to the present disclosure.

FIG. 12 is a cross-sectional view illustrating an exemplary low-temperature electrostatic chuck according to the present disclosure.

### MODE OF THE DISCLOSURE

Hereinafter, exemplary embodiments of the present invention will be described in detail with reference to the accompanying drawings.

Exemplary embodiments of the present disclosure are provided to more fully explain the present invention to those skilled in the art, the following embodiments may be modified in several different forms, and the scope of the present invention is not limited to the following embodiments. However, these embodiments are provided to make the present disclosure thorough and complete, and to fully convey the scope of the present invention to those skilled in the art.

In addition, in the accompanying drawings, the thickness or size of each layer is exaggerated for convenience and clarity of description, and like reference numerals refer to like elements in the drawings. As used herein, term “and/or” includes any one and all combinations of one or more of the listed items. In addition, in this specification, when member A is referred to as being “connected to” member B, the description includes a case of member A and member B being directly connected to each other, and a case of member A and member B being indirectly connected to each other with member C interposed between member A and member B.

Terms used in this specification are used to describe specific embodiments and are not intended to limit the present invention. As used herein, the singular forms may include the plural forms unless the context clearly indicates otherwise. In addition, it will be understood that terms “comprise,” “include,” “comprising,” and/or “including,” when used herein, specify some stated shapes, integers, steps, operations, members, elements, and/or groups thereof, but do not preclude the presence or addition of one or more other shapes, integers, steps, operations, members, elements, and/or groups thereof.

It should be understood that, although the terms “first,” “second,” etc. may be used herein to describe various members, parts, regions, layers, and/or portions, these members, parts, regions, layers, and/or portions are not limited by these terms. These terms are only used to distinguish one member, part, region, layer, or portion from another member, part, region, layer, or portion. Therefore, a first member, part, region, layer, or portion which will be described below in detail may be referred to as a second member, part, region, layer, or portion without departing from the teachings of the present invention.

Space-related terms such as “beneath,” “below,” “lower,” “above,” and “upper” may be used to facilitate understanding of one element or feature and another element or feature illustrated in the drawings. The space-related terms are for easy understanding of the present invention according to various process conditions or use conditions of the present invention, and are not intended to limit the present invention. For example, when an element or feature in the drawing is turned over, an element or feature that would be described as “lower” or “below” becomes an element or feature described as “upper” or “above.” Therefore, “lower” is a concept encompassing “upper” or “below.”

First, a coating-type low-temperature electrostatic chuck will be described.

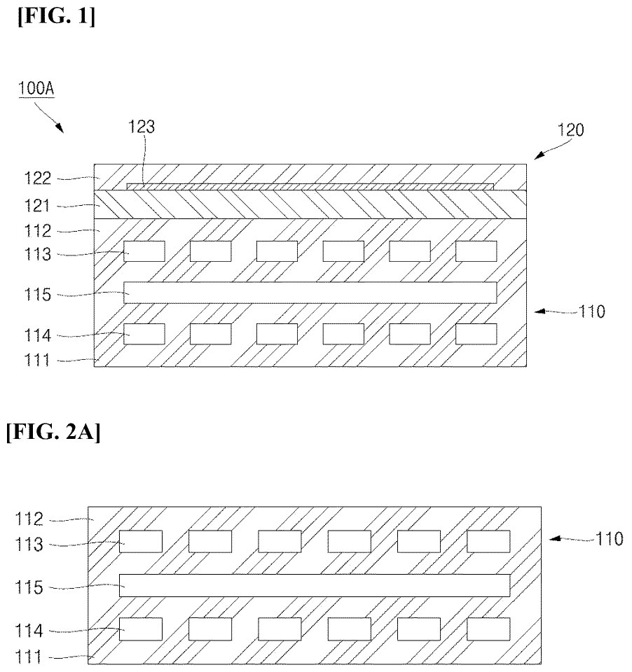

FIG. 1 is a cross-sectional view illustrating an exemplary low-temperature electrostatic chuck 100A according to the present disclosure. In the example illustrated in FIG. 1, the exemplary the low-temperature electrostatic chuck 100A according to the present disclosure may include a base member 110 and a support member 120.

The base member 110 may include a lower region 111 and an upper region 112 provided on the lower region 111. In some embodiments, a plurality of first flow paths 113 through which a first fluid at a first temperature flows may be provided in the upper region 112 with a predetermined pitch, and a plurality of second flow paths 114 through which a second fluid at a second temperature higher than the first temperature flows may be provided in the lower region 111 with a predetermined pitch.

In some embodiments, the first temperature may range from about −200° C. to about 0° C., and the second temperature may range from about 0° C. to about 80° C. In some embodiments, the first fluid and the second fluid may include He, Ne, Ar, Kr, or Xe in a liquid or gaseous state. The first fluid and the second fluid may differ only in temperature and be made of the same material, or may differ in temperature and be made of different materials.

Although the plurality of first flow paths 113 and the plurality of second flow paths 114 are illustrated in the cross-sectional view of FIG. 1, the first flow path 113 and the second flow path 114 may be provided in the form of one or a plurality of vortexes or spirals in a substantially plan view.

In some embodiments, the base member 110 may further include a long heat-blocking cavity 115 provided between the first flow paths 113 and the second flow paths 114.

In some embodiments, the inside of the heat-blocking cavity 115 is empty, and accordingly, mutual heat exchanging may be blocked and not performed between the first flow paths 113 and the second flow paths 114.

Accordingly, the first temperature (e.g., about −200° C. to about 0° C.) of the first flow paths 113 may be maintained in the upper region 112 of the base member 110, and the second temperature (e.g., about 0° C. to about 80° C.) of the second flow paths 114 may be maintained in the lower region 111 of the base member 110.

In some embodiments, a thickness of the heat-blocking cavity 115 may range from about 1% to about 30% of a thickness of the base member 110. When the thickness of the heat-blocking cavity 115 is smaller than about 1% of the thickness of the base member 110, a heat-blocking effect between the upper region 112 and the lower region 111 of the base member 110 can be reduced, and when the thickness of the heat-blocking cavity 115 is greater than about 30% of the thickness of the base member 110, the thickness of the base member 110 can be relatively (unnecessarily) increased. In some embodiments, the heat-blocking cavity 115 may be filled with a heat insulating material (e.g., aerogel, perlite, foamed glass, mineral wool, glass wool, etc.). In some embodiments, yttria-stabilized zirconia (YSZ) or Al₂TiO₅ having low thermal conductivity may be applied on an upper and/or lower surface of the heat-blocking cavity 115, or an YSZ plate or an Al₂TiO₅ plate may be coupled to the upper and/or lower surface of the heat-blocking cavity 115.

In some embodiments, the lower region 111 of the base member 110 may be directly or indirectly coupled to equipment. As described above, even when the upper region 112 of the base member 110 is maintained at a low temperature of about −200° C. to about 0° C., the lower region 111 of the base member 110 may be maintained at a temperature of about 0° C. to about 80° C. (preferably maintained at room temperature of about 1°C. to 35° C.), and thus frost, ice, or moisture is not formed in an attachment region of etching equipment to which the low-temperature electrostatic chuck 100A is coupled. Therefore, it is possible to prevent defects of the semiconductor wafer from occurring due to moisture during the semiconductor manufacturing process.

In some embodiments, the base member 110 may be made of pure titanium, a titanium alloy, pure aluminum, or an aluminum alloy. For reference, pure titanium and/or a titanium alloy may have a thermal expansion coefficient (unit: m/m °C.) of about 7×10⁻⁶ to about 11×10⁻⁶, and pure aluminum and/or an aluminum alloy may have a thermal expansion coefficient of 23×10⁻⁶.

The support member 120 may be provided directly on the base member 110 without a bonding layer. In some embodiments, the support member 120 may include a first dielectric layer 121, an electrode layer 123, and a second dielectric layer 122. The first dielectric layer 121 may be provided to be directly applied on the base member 110 without a bonding layer. The electrode layer 123 may be provided on the first dielectric layer 121. The second dielectric layer 122 may be provided to be directly applied on the first dielectric layer 121 and the electrode layer 123.

In some embodiments, the first dielectric layer 121 may be provided to be directly applied on the base member 110 by an atmospheric pressure plasma spraying method. In some embodiments, the second dielectric layer 122 may be provided to be directly applied on the electrode layer 123 and the first dielectric layer 121 by an atmospheric pressure plasma spraying method. In some embodiments, in addition to the atmospheric pressure plasma spraying method, an aerosol deposition, arc spraying, high velocity oxyfuel spraying, cold spraying, or flame spraying method may be used.

In some embodiments, at least one of the first and second dielectric layers 121 and 122 may be made of a ceramic. In some embodiments, at least one of the first and second dielectric layers 121 and 122 may include zirconia (ZrO₂), beryllium oxide (BeO), aluminum oxide (Al₂O₃), aluminum nitride (AlN), silicon carbide (SiC), silicon nitride (Si₃N₄), or aluminum titanate (Al₂TiO₅). In some embodiments, at least one of the first and second dielectric layers 121 and 122 may include yttrium oxide (Y2O₃), yttrium oxyfluoride (YOF), or yttrium fluoride (YF₃). For reference, a thermal expansion coefficient of zirconia is about 11×10⁻⁶, a thermal expansion coefficient of beryllium oxide is about 8×10⁻⁶, a thermal expansion coefficient of aluminum oxide is about 7.3×10⁻⁶, a thermal expansion coefficient of aluminum nitride is about 4.4×10⁻⁶, a thermal expansion coefficient of silicon carbide is about 3.7×10⁻⁶, a thermal expansion coefficient of silicon nitride is about 3.4×10⁻⁶, a thermal expansion coefficient of aluminum titanate is about 1×10⁻⁶, and a thermal expansion coefficient of yttrium oxide, yttrium oxyfluoride, or yttrium fluoride ranges from about 10 to about 10.5×10⁻⁶.

Therefore, materials having a small difference in thermal expansion coefficient may be appropriately selected as materials of the base member 110 and the support member 120 so that a warpage of the low-temperature electrostatic chuck 100A caused by the difference in thermal expansion coefficient can be minimized.

In some embodiments, when the base member 110 and/or the support member 120 are used for a semiconductor wafer, the base member 110 and/or the support member 120 may be provided in the form of a substantial disk shape when viewed from the top. In some embodiments, when the base member 110 and/or the support member 120 are used for a display glass, the base member 110 and/or the support member 120 may be provided in the form of a substantially quadrilateral plate shape when viewed from the top.

In some embodiments, when the low-temperature electrostatic chuck 100A is used for semiconductor manufacturing, a diameter of the support member 120 may range from about 100 mm to about 400 mm. In some embodiments, when the low-temperature electrostatic chuck 100A is used for display manufacturing, a length of one side of the support member 120 may range from about 400 mm to about 3,500 mm.

In this way, in the present disclosure, the heat-blocking cavity 115 is further provided between the upper region and the lower region to prevent heat in the upper region from being transmitted to the lower region, and thus it is possible to provide the low-temperature electrostatic chuck 100A that does not for frost, ice, or moisture on the equipment and can be directly or indirectly mounted on etching equipment.

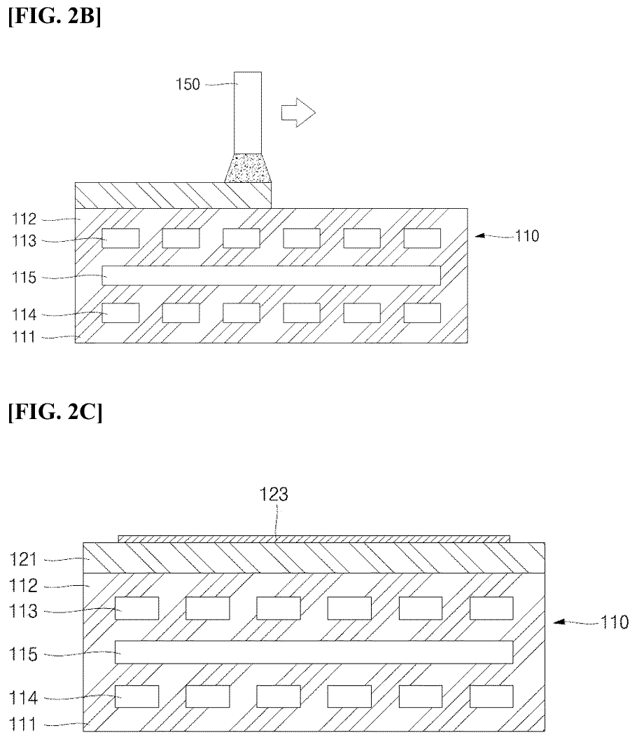

FIGS. 2A to 2D are schematic views illustrating a method of manufacturing the exemplary low-temperature electrostatic chuck 100A according to the present disclosure.

FIG. 2A illustrates an initial stage of manufacturing of the exemplary low-temperature electrostatic chuck 100A according to the present disclosure. A plurality of first flow paths 113 through which a first fluid at a first temperature flows may be provided in an upper region 112, a plurality of second flow paths 114 through which a second fluid at a second temperature higher than the first temperature flows may be provided in a lower region 111, and a base member 110 having a heat-blocking cavity 115 may be provided between the first flow paths 113 and the second flow paths 114. In some embodiments, the base member 110 may be made of pure titanium, a titanium alloy, pure aluminum, or an aluminum alloy.

FIG. 2B illustrates a post-stage of manufacturing of the exemplary low-temperature electrostatic chuck 100A according to the present disclosure. A first dielectric layer 121 may be directly applied on the base member 110. In some embodiments, aluminum oxide powder may be directly applied on the base member 110 by an atmospheric pressure plasma spraying method. Accordingly, there is no bonding layer between the base member 110 and the first dielectric layer 121, and the first dielectric layer 121 may be provided directly on the base member 110. Reference numeral 150 in the drawing, which is not described, is a powder spray nozzle.

FIG. 2C illustrates a post-stage of manufacturing of the exemplary low-temperature electrostatic chuck 100A according to the present disclosure. An electrode layer 123 may be provided on the first dielectric layer 121. The electrode layer 123 may also be provided by a plating method or various spraying methods described above. The electrode layer 123 may include tungsten (W) and/or titanium (Ti).

FIG. 2D illustrates a post-stage of manufacturing of the exemplary low-temperature electrostatic chuck 100A according to the present disclosure. A second dielectric layer 122 may be directly applied on the first dielectric layer 121 and the electrode layer 123. In some embodiments, aluminum oxide powder may be applied on the first dielectric layer 121 and the electrode layer 123 by an atmospheric pressure plasma spraying method. Here, the first dielectric layer 121, the electrode layer 123, and the second dielectric layer 122 may be defined or referred to as a support member 120.

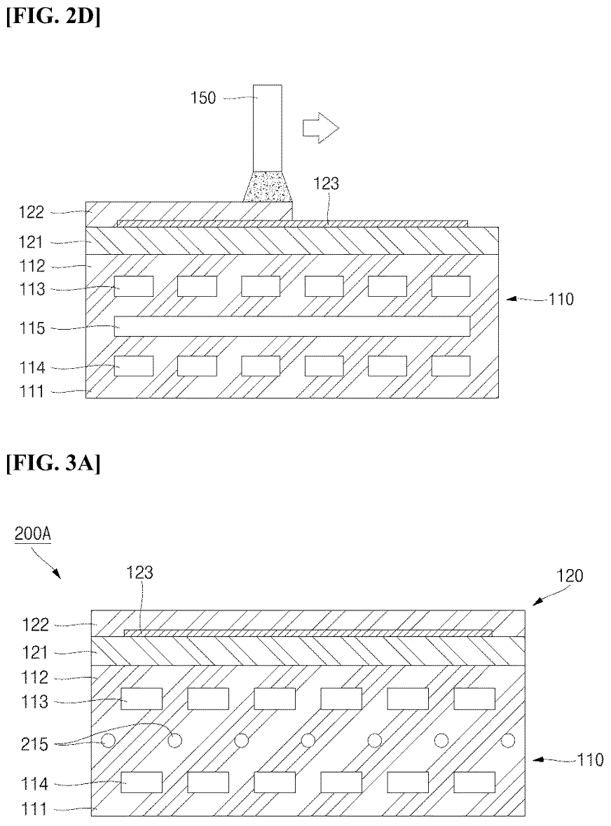

FIGS. 3A and 3B are cross-sectional views illustrating other exemplary low-temperature electrostatic chucks 200A and 200B according to the present disclosure.

In the examples illustrated in FIGS. 3A and 3B, the exemplary low-temperature electrostatic chuck 200A according to the present disclosure may include heat-blocking heaters 215. In some embodiments, the heat-blocking heaters 215 may be provided substantially in parallel between first flow paths 113 and second flow paths 114. In some embodiments, the heat-blocking heater 215 may include a nickel-chrome heating wire and an insulator surrounding the nickel-chrome heating wire. Although the heat-blocking heater 215 is illustrated as being provided with a plurality of heat-blocking heaters 215 in the cross-sectional views of FIGS. 3A and 3B, the heat-blocking heater 215 may be provided in the form of one or a plurality of vortexes or spirals in a substantially plan view. Heat of the first flow paths 113 is not transmitted to the second flow paths 114 due to the heat-blocking heaters 215, and thus a temperature of the second flow path 114 may be adjusted to be similar to a temperature (e.g., room temperature) of equipment.

In some embodiments, positions of the heat-blocking heaters 215 may be provided at positions that do not correspond to the first flow paths 113 and the second flow paths 114 (vertically staggered) (see FIG. 3A), or the positions of the heat-blocking heaters 215 may be provided at positions that correspond to the first flow paths 113 and the second flow paths 114 (the same in a vertical direction) (see FIG. 3B).

Meanwhile, in the low-temperature electrostatic chucks 200A and 200B according to the present disclosure, after an etching process of a semiconductor wafer is completed at an extremely low temperature, the operation of the first flow path 113 stops, and instead, the temperature of the heat-blocking heaters 215 may be further increased.

For example, by increasing the temperature of the heat-blocking heaters 215 to a range of 50° C. to about 100° C., the temperature of the semiconductor wafer also reaches the above temperature range, and thus it is possible to prevent moisture from condensing on a surface of the semiconductor wafer when the semiconductor wafer is unloaded from a process chamber.

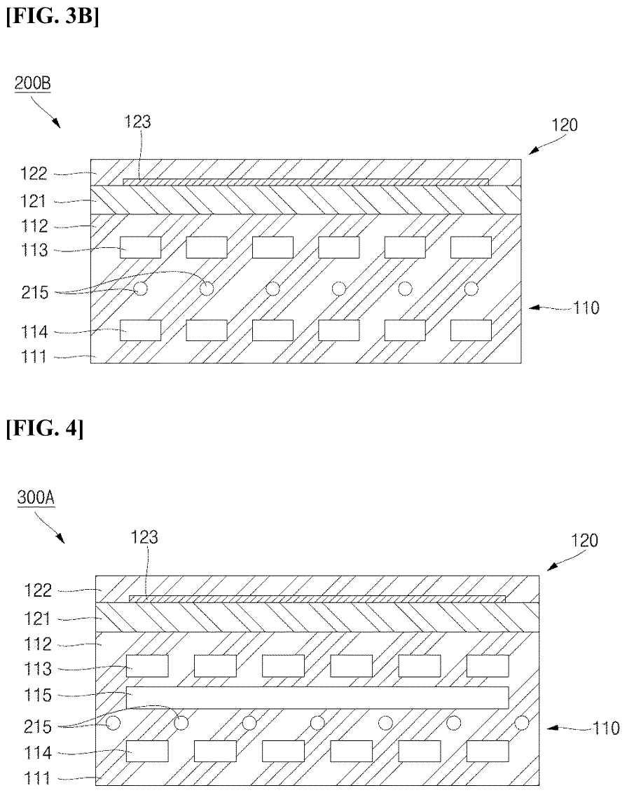

FIG. 4 is a cross-sectional view illustrating an exemplary low-temperature electrostatic chuck 300A according to the present disclosure.

In the example illustrated in FIG. 4, the exemplary low-temperature electrostatic chuck 300A according to the present disclosure may further include a heat-blocking cavity 115 and heat-blocking heaters 215. In some embodiments, the heat-blocking cavity 115 and the heat-blocking heaters 215 may be provided substantially in parallel between first flow paths 113 and second flow paths 114. In some embodiments, the heat-blocking cavity 115 may be positioned at an upper side and the heat-blocking heaters 215 may be positioned at a lower side, or vice versa. Heat of the first flow path 113 is not transmitted to the second flow path 114 due to the heat-blocking cavity 115 and the heat-blocking heaters 215, and thus a temperature of the second flow path 114 may be adjusted to be similar to a temperature of equipment. Further, after an etching process is completed, a temperature of a semiconductor wafer may be rapidly increased to room temperature using the heat-blocking heaters 215.

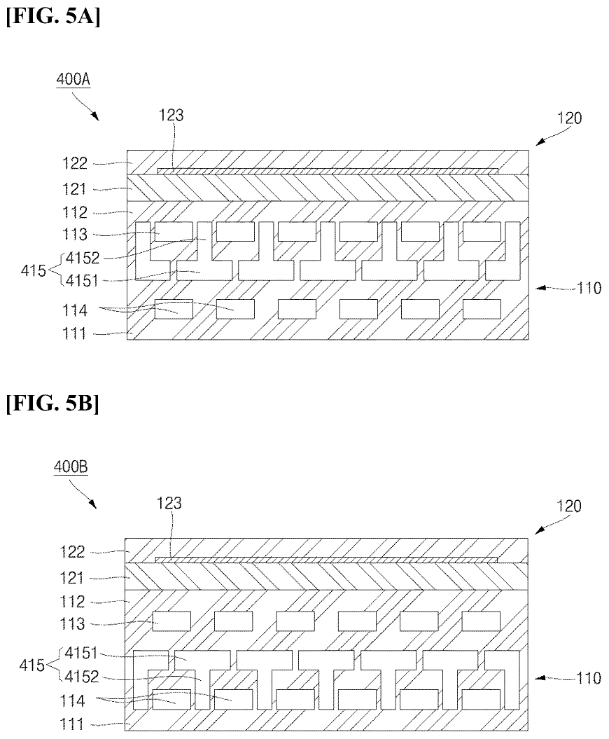

FIGS. 5A to 5C are cross-sectional views illustrating exemplary low-temperature electrostatic chucks 400A, 400B, and 400C according to the present disclosure.

In some embodiments, as in the electrostatic chuck 400A illustrated in FIG. 5A, a heat-blocking cavity 415 may include first heat-blocking cavities 4151 provided between first flow paths 113 and second flow paths 114, and second heat-blocking cavities 4152 which are provided between the first flow paths 113 and connected to the first heat-blocking cavities 4151. In some embodiments, a width of the first heat-blocking cavity 4151 may be greater than a width of the second heat-blocking cavity 4152. In some embodiments, the heat-blocking cavity 415 may have a cross section with a substantially ⊥ shape. A region between the first heat-blocking cavities 4151 may be defined as a partition, and a region between the second heat-blocking cavity 4152 and the first flow path 113 may also be defined as a partition.

In some embodiments, as in the electrostatic chuck 400B illustrated in FIG. 5B, a heat-blocking cavity 415 may include first heat-blocking cavities 4151 provided between first flow paths 113 and second flow paths 114, and second heat-blocking cavities 4152 which are provided between the second flow paths 114 and connected to the first heat-blocking cavities 4151. In some embodiments, a width of the first heat-blocking cavity 4151 may be greater than a width of the second heat-blocking cavity 4152. In some embodiments, the heat-blocking cavity 415 may have a cross section with a substantially ⊥ shape. A region between the second heat-blocking cavity 4152 and the second flow path 114 may be defined as a partition.

In some embodiments, as in the electrostatic chuck 400C illustrated in FIG. 5C, a heat-blocking cavity 415 may include a first heat-blocking cavities 4151 provided between first flow paths 113 and second flow paths 114, a second heat-blocking cavities 4152 provided between the first flow paths 113 and connected to the first heat-blocking cavities 4151, and third heat-blocking cavities 4153 provided between the second flow paths 114 and connected to the first heat-blocking cavities 4151. In some embodiments, a width of the first heat-blocking cavity 4151 may be greater than widths of the second and third heat-blocking cavities 4152 and 4153. In some embodiments, the heat-blocking cavity 415 may have a cross section with a substantially+shape.

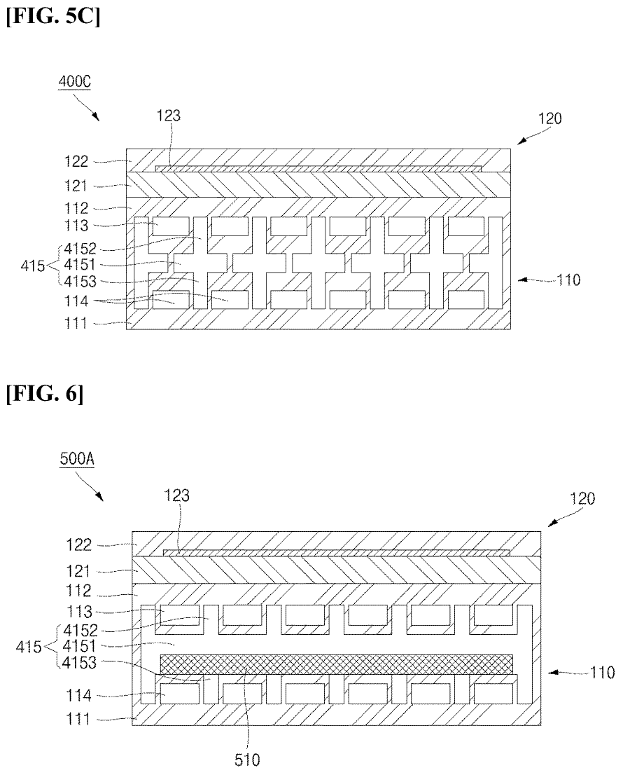

FIG. 6 is a cross-sectional view illustrating an exemplary low-temperature electrostatic chuck 500A according to the present disclosure.

As illustrated in FIG. 6, in the exemplary low-temperature electrostatic chuck 500A according to the present disclosure, in particular, a base member 110 may include heat-blocking cavities 415 provided between first flow paths 113 and second flow paths 114, and further include a heat insulating material 510 having a thermal conductivity of less than about 10, which is provided in the heat-blocking cavities 415.

In some embodiments, the heat insulating material 510 may include yttria-stabilized zirconia (YSZ) or Al₂TiO₅ applied on the heat-blocking cavities 415, or include an YSZ plate or Al₂TiO₅ plate coupled to the heat-blocking cavities 415. In some embodiments, most materials of which their thermal conductivity ranges from about 0.1 W/mk to about 0.35 W/mK may be used as the heat insulating material 510. In some embodiments, a height (thickness) of the heat insulating material 510 may be smaller than a height (thickness) of the heat-blocking cavity 415, and thus an upper region and/or lower region of the heat-blocking cavity 415 may remain in a substantially cavity form.

In some embodiments, the heat-blocking cavity 415 may include a first heat-blocking cavity 4151 elongated between the first flow paths 113 and the second flow paths 114, a second heat-blocking cavity 4152 provided between the first flow paths 113 and connected to the first heat-blocking cavity 4151, and a third heat-blocking cavity 4153 provided between the second flow paths 114 and connected to the first heat-blocking cavity 4151. In some examples, the heat insulating material 510 may be positioned in a first heat-blocking cavity 4151 that is long and extends between the first flow paths 113 and the second flow paths 114.

In this way, in the present disclosure, a structure may be provided in which a lower region 111 (relatively high-temperature region) and an upper region 112 (relatively low temperature the region) of the base member 110 do not easily exchange heat with each other, and thus it is possible to provide various low-temperature electrostatic chucks that does not form frost, ice, or, moisture on equipment and can be mounted on the equipment.

Next, a bonding-type low-temperature electrostatic chuck will be described. Here, descriptions of structures, materials, and/or functions identical to those of the coating-type low-temperature electrostatic chuck, will be kept brief.

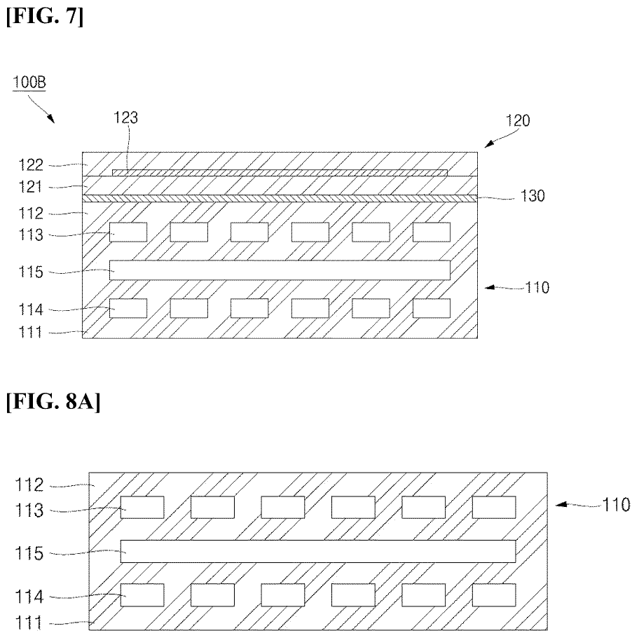

FIG. 7 is a cross-sectional view illustrating an exemplary low-temperature electrostatic chuck 100B according to the present disclosure. In the example illustrated in FIG. 7, the exemplary low-temperature electrostatic chuck 100B according to the present disclosure may include a base member 110, a support member 120, and a bonding layer 130.

The bonding layer 130 may be interposed between the base member 110 and the support member 120. In some embodiments, the bonding layer 130 may include a silicone polymer-based material or a metal-based material. In some embodiments, the silicone polymer-based bonding layer allows an electrostatic chuck to be used in a temperature range of about −200° C. to about 0° C., and the metal-based bonding layer allows an electrostatic chuck to be used in a temperature range of about 0° C. to about 80° C.

In some embodiments, the silicone polymer-based bonding layer may include at least one of one-component silicone, two-component silicone, one-component epoxy, two-component epoxy, and polyurethane having a thermal conductivity of about 0.3 W/mK to about 3 W/mK.

In some embodiments, the one-component silicone (or one-component epoxy) starts to harden only when the one-component silicone reacts with moisture in the air, and thus, when the one-component silicone is applied on the base member 110 while being stored in a container that prevents contact with the air, the hardening gradually spreads inward from the surface. In some embodiments, the two-component silicone (or two-component epoxy) hardens when two components (hardener and main agent) are mixed on the base member 110 regardless of moisture in the air. In some embodiments, a polyurethane adhesive may also include one-component polyurethane or two-component polyurethane.

In some embodiments, the bonding layer 130 may further include nano fillers such as ceramic fillers or metal fillers to improve thermal conductivity. In some embodiments, an average size of the nano fillers may range from about 1 nm to about 10 μm. In some embodiments, a weight (wt %) of the nano fillers may range from about 5 wt % to about 95 wt %. When the weight of the nano fillers is less than about 5 wt %, the thermal conductivity may be lower than a target value. When the weight of the nano fillers is greater than about 95%, the adhesive may be difficult to spray/apply due to a relatively high viscosity. In some embodiments, a thickness of the bonding layer 130 may range from about 1 μm to about 100 mm. When the thickness of the bonding layer 130 is less than about 1 μm, the thermal conductivity is excellent, but thermal diffusion performance is degraded, and thus the thermal uniformity of the support member 120 may be low. When the thickness of the bonding layer 130 is greater than about 100 mm, the heat diffusion performance is excellent, and thus the thermal uniformity of the support member 120 may be increased, but the thermal conductivity may be low.

In some embodiments, the nano fillers may include pure titanium (CTE: 8.6), beryllium oxide (CTE: 8), and/or aluminum oxide (CTE: 7.3). In some embodiments, the nano fillers may include a material (metal or ceramic) similar to or the same as the base member 110 and/or the support member 120.

In some embodiments, the metal-based bonding layer 130 may include a metalized brazing layer, an active metal brazing layer, a diffusion bonding layer, a friction welding layer, and/or a laser welding layer between the base member (i.e., metal) 110 and the support member (i.e., ceramic) 120. In addition, bonding using a glass frit, metal brazing bonding, diffusion bonding, and/or diffusion brazing bonding may also be used.

As an example, the metalized brazing layer may be provided by forming a metal layer on a surface of a ceramic and then bonding the metal layer and the ceramic using a brazing alloy. As a method of forming the metal layer, a method of applying an intermetallic compound and precipitating a metal by thermal decomposition and reacting with a ceramic, a method of precipitating a metal in a gas phase, a method of plating by a physical method such as a vapor deposition method, a sputtering method, etc. may be used. For example, a method using Mo-Mn may be used. The above method is a method in which a Mo or Mo-Mn powder is made into a paste in an organic solvent as a binder, applied to a ceramic, and metallized and brazed. For example, stabilized zirconia (PSZ) and Ti-6Al-4V may be bonded at about 820° C. by metalizing Ti. For example, after metalizing a surface of zirconia with Ti, stabilized zirconia (PSZ) and Ti-6Al-4V, the metalized surface may be bonded using an Ag-28Cu-based brazing alloy. In some embodiments, a black reaction layer made of a Ti—O compound (TiO, Ti₂O₃, Ti₃O₅, TiO₂, etc.) may be provided on a surface of the metallized zirconia to improve the wettability of the ceramic surface, thereby implementing high bonding performance.

For example, the active metal brazing layer may be suitable for a mass production process which can economically manufacture small products with high reliability and using which complex-shaped products should be bonded in one operation. An alloy obtained by adding an appropriate amount of an active metal of Group IV such as Ti, Zr, or the like to a soft metal such as Ni, Cu, or Ag is used as a brazing alloy to perform direct bonding in a vacuum or in an inert atmosphere. The active metals such as Ti, Zr, and the like contained in the brazing alloy react with the ceramic to perform bonding by forming oxides, nitrides, or carbides at an interface. Further, Ag, Cu, etc. are segregated in the center to form a soft layer and have a stress relieving effect, thereby improving bonding strength.

In some embodiments, the diffusion bonding layer is a layer obtained by bringing two materials into close contact with each other and using diffusion of atoms that occurs between the bonding surfaces. The diffusion bonding layer is characterized by low thermal stress or deformation after bonding and low material degradation caused by structural changes, and it is possible to bond not only the same materials but also different materials with different properties and to bond complex shapes. There are a method of bonding materials by pressing and heating under stress that hardly deforms a metal and a method of bonding materials by heating and pressurizing so that a metal is deformed. The bonding is performed through a three-step process of plastic deformation by high-temperature creep, removal of voids by diffusion of atoms, and grain boundary movement. In the diffusion bonding method, controlling the vacuum atmosphere, heating and maintaining the temperature of the bonding material, reducing thermal stress generated when the temperature rises and falls, and the like are important factors for bonding.

In some embodiments, the friction welding layer may be obtained by rotating a metal and a ceramic while pressing the metal and the ceramic, heating the metal and the ceramic with frictional heat, and applying pressure when a temperature reaches a certain temperature.

In some embodiments, the laser welding layer is a layer obtained using high-density energy as a heat source, and high-power lasers include a CO2 laser and a Nd; YAG laser. Although the laser is for thermal processing, it is possible to obtain high energy density (more than 10⁶W/cm² ) by reducing the size of the beam, and thus the heat effect is small, welding may be performed within a small deformation range, and fine welding is possible due to high controllability of input energy.

In this way, in the present disclosure, the bonding layer 130 having high thermal conductivity is interposed between the base member 110 and the support member 120, and thus a distance between the first flow path 113 in the base member 110 and the support member 120 may be relatively increased so that the low-temperature electrostatic chuck 100B having high temperature uniformity on the support member 120 may be provided.

In some embodiments, the electrostatic chuck may be used in a temperature range of about −200° C. to about 0° C. In some embodiments, a standard deviation of the thermal expansion coefficients of the base member 110, the support member 120, and the bonding layer 130 may range from about 0.01% to about 10%. Therefore, in the range of about −200° C. to about 0° C., which is a use temperature of the electrostatic chuck, a warpage caused by a difference in thermal expansion coefficients between the base member 110, the support member 120, and the bonding layer 130 may be minimized, and accordingly, the flatness of the electrostatic chuck may be excellently maintained in a low-temperature environment.

In some embodiments, when the base member 110 is made of pure titanium (CTE: 8.6), the first and second dielectric layers 121 and 122 constituting the support member 120 are made of beryllium oxide (CTE: 8), and the bonding layer 130 is made of pure titanium (CTE: 8.6) or beryllium oxide (CTE: 8), a standard deviation of the CTEs may be about 0.4%. In some embodiments, when the base member 110 is made of pure titanium (CTE: 8.6), the first and second dielectric layers 121 and 122 constituting the support member 120 are made of aluminum oxide (CTE: 7.3), and the bonding layer 130 is made of aluminum oxide (CTE: 7.3), the standard deviation of the CTEs may be about 0.9%.

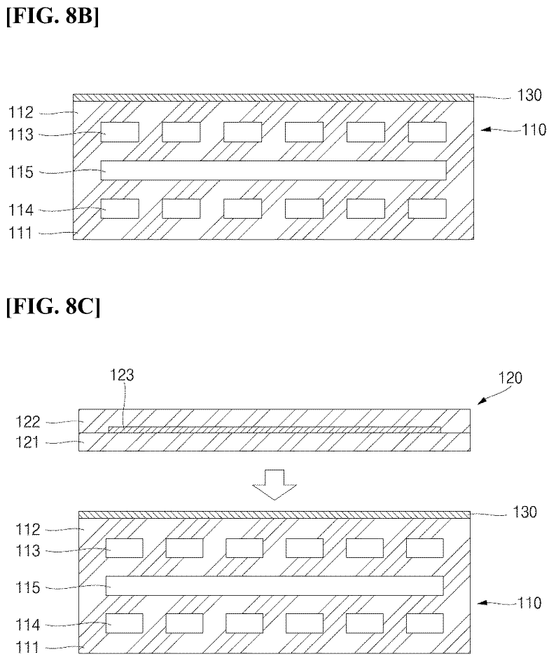

FIGS. 8A to 8C are schematic views illustrating a method of manufacturing the exemplary low-temperature electrostatic chuck 100B according to the present disclosure.

FIG. 8A illustrates an initial stage of manufacturing of the exemplary low-temperature electrostatic chuck 100B according to the present disclosure. A plurality of first flow paths 113 through which a first fluid at a first temperature flows may be provided in an upper region 112, a plurality of second flow paths 114 through which a second fluid at a second temperature higher than the first temperature flows may be provided in a lower region 111, and a base member 110 having a heat-blocking cavity 115 may be provided between the first flow paths 113 and the second flow paths 114. In some embodiments, the base member 110 may be made of pure titanium, a titanium alloy, or aluminum.

FIG. 8B illustrates a post-stage of manufacturing of the exemplary low-temperature electrostatic chuck 100B according to the present disclosure. A bonding layer 130 may be provided on the base member 110. In some embodiments, the bonding layer 130 may be provided on the base member 110 through a dispenser, a sprayer, a jetting device, a three-dimensional (3D) printer, or the like. The bonding layer 130 may be provided on the entire upper surface of the base member 110 or in the form of a dot array on the entire upper surface.

FIG. 8C illustrates a post-stage of manufacturing of the exemplary low-temperature electrostatic chuck 100B according to the present disclosure. The support member 120 including a first dielectric layer 121, a second dielectric layer 122, and an electrode layer 123 may be attached to the bonding layer 130. In some embodiments, the first dielectric layer 121 may be made of aluminum oxide. In some embodiments, the first dielectric layer 121 may be provided in the form of a plate through a sintering process. In some embodiments, the electrode layer 123 may be provided on the first dielectric layer 121. The electrode layer 123 may be provided by a plating method or various spray methods. The electrode layer 123 may include tungsten (W) and/or titanium (Ti). In some embodiments, the second dielectric layer 122 may be directly applied on the first dielectric layer 121 and the electrode layer 123. In some embodiments, aluminum oxide powder may be applied on the first dielectric layer 121 and the electrode layer 123 by an atmospheric pressure plasma spraying method.

In this way, the base member 110 includes titanium and the support member 120 and the bonding layer 130 include aluminum oxide, and thus a standard deviation of thermal expansion coefficients of the base member 110, the support member 120, and the bonding layer 130 is smaller than about 2%, and therefore, even when the electrostatic chuck is used in a low-temperature environment in a range of about −200° C. to about 0° C., a warpage of the base member 110, the support member 120, and the bonding layer 130 hardly occurs and excellent flatness is maintained. Therefore, a fixing force of a glass or wafer by the electrostatic chuck may be maintained excellently.

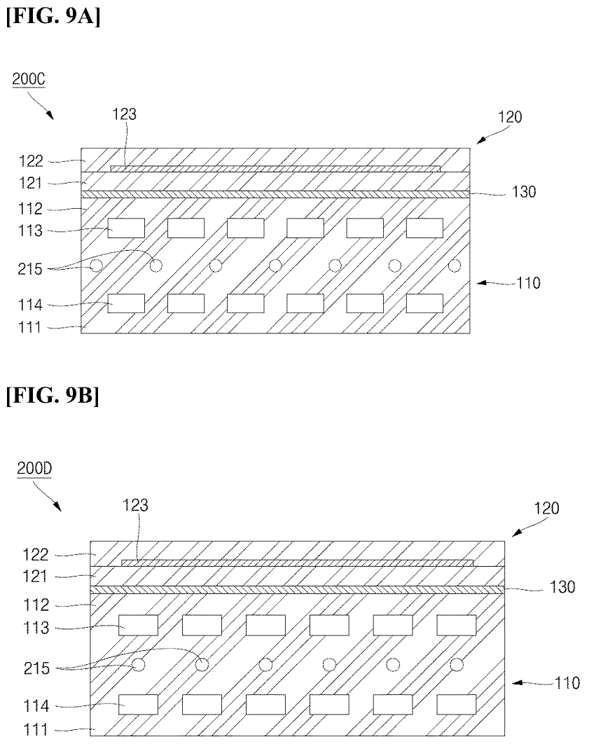

FIGS. 9A and 9B are cross-sectional views illustrating other exemplary low-temperature electrostatic chucks 200C and 200D according to the present disclosure.

In the example illustrated in FIGS. 9A and 9B, the exemplary low-temperature electrostatic chucks 200C and 200D according to the present disclosure may include heat-blocking heaters 215. In some embodiments, the heat-blocking heaters 215 may be provided substantially in parallel between first flow paths 113 and second flow paths 114. In some embodiments, the heat-blocking heater 215 may include a nickel-chrome heating wire and an insulator surrounding the nickel-chrome heating wire. Heat of the first flow paths 113 is not transmitted to the second flow paths 114 due to the heat-blocking heaters 215, and thus a temperature of the second flow path 114 may be adjusted to be similar to a temperature (e.g., room temperature) of equipment.

In some embodiments, positions of the heat-blocking heaters 215 may be provided at positions that do not correspond to the first flow paths 113 and the second flow paths 114 (vertically staggered) (see FIG. 9A), or the positions of the heat-blocking heater 215 may be provided at positions that correspond to the first flow paths 113 and the second flow paths 114 (the same in s vertical direction) (see FIG. 9B).

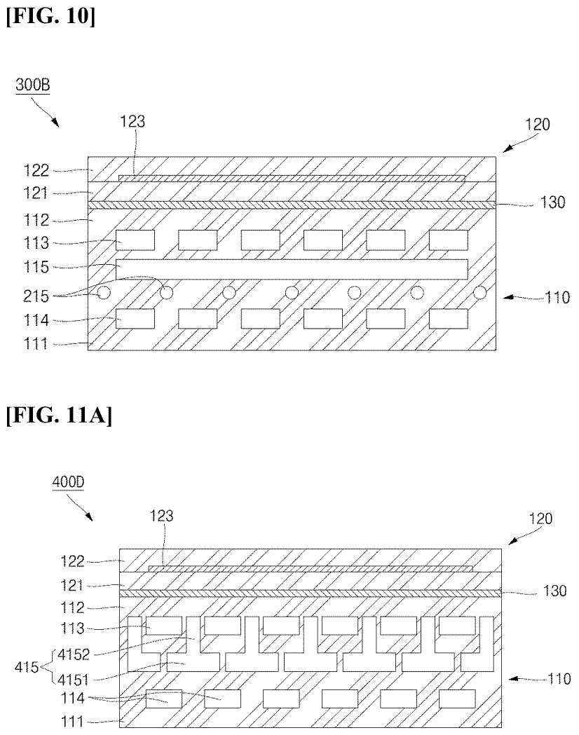

FIG. 10 is a cross-sectional view illustrating an exemplary low-temperature electrostatic chuck 300B according to the present disclosure.

In the example illustrated in FIG. 10, the exemplary low-temperature electrostatic chuck 300B according to the present disclosure may further include a heat-blocking cavity 115 and heat-blocking heaters 215. In some embodiments, the heat-blocking cavity 115 and the heat-blocking heaters 215 may be provided in parallel between first flow paths 113 and second flow paths 114. In some embodiments, the heat-blocking cavity 115 may be positioned on an upper side and the heat-blocking heaters 215 may be positioned on a lower side, or vice versa.

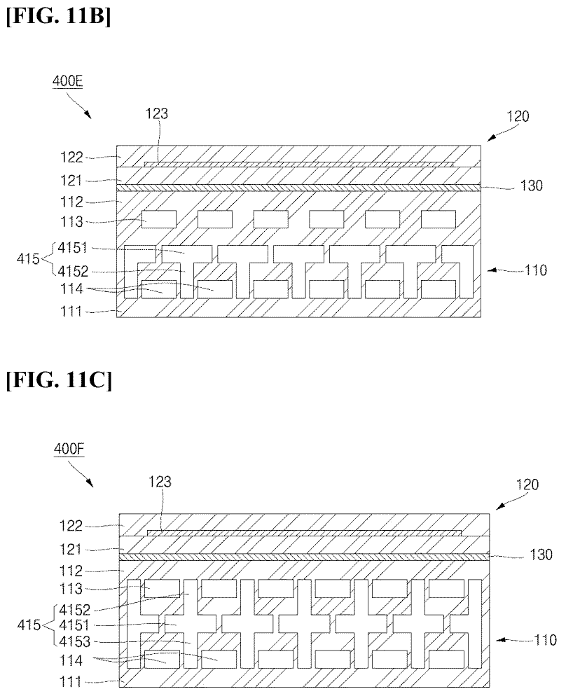

FIGS. 11A to 11C are cross-sectional views illustrating exemplary low-temperature electrostatic chucks 400D, 400E, and 400F according to the present disclosure.

In some embodiments, as in the electrostatic chuck 400D illustrated in FIG. 11A, a heat-blocking cavity 415 may include first heat-blocking cavities 4151 provided between first flow paths 113 and second flow paths 114, and second heat-blocking cavities 4152 which are provided between the first flow paths 113 and connected to the first heat-blocking cavities 4151.

In some embodiments, as in the electrostatic chuck 400E illustrated in FIG. 11B, a heat-blocking cavity 415 may include first heat-blocking cavities 4151 provided between first flow paths 113 and second flow paths 114, and second heat-blocking cavities 4152 which are provided between the second flow paths 114 and connected to the first heat-blocking cavities 4151.

In some embodiments, as in the electrostatic chuck 400F illustrated in FIG. 11C, a heat-blocking cavity 415 may include first heat-blocking cavities 4151 provided between first flow paths 113 and second flow paths 114, second heat-blocking cavities 4152 which are provided between the first flow paths 113 and connected to the first heat-blocking cavities 4151, and third heat-blocking cavities 4153 which are provided between the second flow paths 114 and connected to the first heat-blocking cavities 4151.

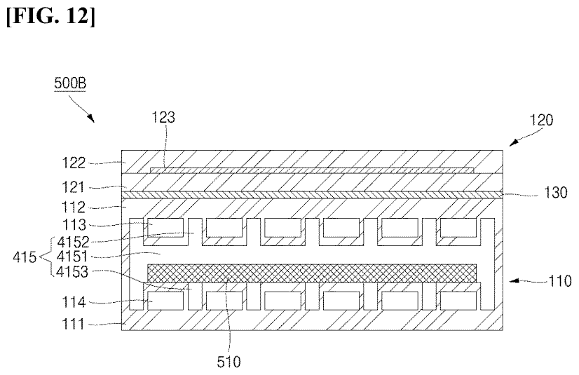

FIG. 12 is a cross-sectional view illustrating an exemplary low-temperature electrostatic chuck 500B according to the present disclosure.

As illustrated in FIG. 12, in the exemplary low-temperature electrostatic chuck 500B according to the present disclosure, in particular, a base member 110 may include heat-blocking cavities 415 provided between first flow paths 113 and second flow paths 114, and further include a heat insulating material 510 having a thermal conductivity of less than about 10, which is provided in the heat-blocking cavities 415.

In some embodiments, the heat insulating material 510 may include yttria-stabilized zirconia (YSZ) or Al₂TiO₅ applied on the heat-blocking cavities 415, or include an YSZ plate or Al₂TiO₅ plate coupled to the heat-blocking cavities 415.

In some embodiments, the heat insulating material 510 may be positioned on a first heat-blocking cavity 4151 that is long and extends between the first flow paths 113 and the second flow paths 114, and additionally, the heat-blocking cavity 415 may further include second heat-blocking cavities 4152 extending between the first flow paths 113 from the first heat-blocking cavity 4151, and third heat-blocking cavities 4153 extending between the second flow paths 114 from the first heat-blocking cavity 4151.

The above description is only of embodiments for implementing the low-temperature electrostatic chuck according to the present disclosure. The present invention is not limited to the above embodiments, and as claimed in the claims below, various modifications may be made without departing from the spirit and scope of the present invention by those skilled in the art to which the present invention pertains.

1. A low-temperature electrostatic chuck comprising:
a base member; and
a support member including a first dielectric layer applied on the base member, an electrode layer provided on the first dielectric layer, and a second dielectric layer applied on the first dielectric layer and the electrode layer,
wherein the base member includes first flow paths provided in an upper region and through which a first fluid at a first temperature flows, and second flow paths provided in a lower region and through which a second fluid at a second temperature higher than the first temperature flows.

2. The low-temperature electrostatic chuck of claim 1, wherein the first temperature ranges from −200° C. to 0° C., and the second temperature ranges from 0° C. to 80° C.

3. The low-temperature electrostatic chuck of claim 1, wherein the base member further includes a heat-blocking cavity provided between the first flow paths and the second flow paths.

4. The low-temperature electrostatic chuck of claim 3, wherein the heat-blocking cavity includes a first heat-blocking cavity provided between the first flow paths and the second flow paths, and a second heat-blocking cavity which is provided between the first flow paths and connected to the first heat-blocking cavity.

5. The low-temperature electrostatic chuck of claim 3, wherein the heat-blocking cavity includes a first heat-blocking cavity provided between the first flow paths and the second flow paths, and a second heat-blocking cavity which is provided between the second flow paths and connected to the first heat-blocking cavity.

6. The low-temperature electrostatic chuck of claim 3, wherein the heat-blocking cavity includes a first heat-blocking cavity provided between the first flow paths and the second flow paths, a second heat-blocking cavity provided between the first flow paths and connected to the first heat-blocking cavity, and a third heat-blocking cavity provided between the second flow paths and connected to the first heat-blocking cavity.

7. The low-temperature electrostatic chuck of claim 3, wherein an inside of the heat-blocking cavity is filled with a heat insulating material.

8. The low-temperature electrostatic chuck of claim 3, wherein an upper or lower surface of the heat-blocking cavity is coated with yttria-stabilized zirconia (YSZ) or coupled to an YSZ plate or is coated with Al₂TiO₅ or coupled to an Al₂TiO₅ plate.

9. The low-temperature electrostatic chuck of claim 1, wherein the base member further includes a heat-blocking heater provided between the first flow path and the second flow path.

10. The low-temperature electrostatic chuck of claim 1, wherein the base member further includes:
a heat-blocking cavity provided between the first flow path and the second flow path; and
a heat-blocking heater provided between the first flow path and the second flow path.

11. The low-temperature electrostatic chuck of claim 1, further comprising a bonding layer interposed between the base member and the support member.

12. The low-temperature electrostatic chuck of claim 11, wherein the bonding layer includes a silicone polymer-based material or a metal-based material.

13. The low-temperature electrostatic chuck of claim 11, wherein the bonding layer includes at least one of one-component silicone, two-component silicone, one-component epoxy, two-component epoxy, and polyurethane having a thermal conductivity of 0.3 W/mK to 3 W/mK.

14. The low-temperature electrostatic chuck of claim 11, wherein the bonding layer includes at least one of a ceramic filler and a metal filler.

15. The low-temperature electrostatic chuck of claim 11, wherein the bonding layer includes a metalized brazing layer, an active metal brazing layer, a diffusion bonding layer, a friction welding layer, or a laser welding layer between the base member and the support member.
